(19) United States
(12) Patent Application Publication
(10) Pub. No.: US 2026/0004026 A1
(43) Pub. Date: Jan. 1, 2026

(54) INDUSTRIAL BASE DESIGN GENERATION USING GENERATIVE ARTIFICIAL INTELLIGENCE

(71) Applicant: Rockwell Automation Technologies, Inc., Mayfield Heights, OH (US)

(72) Inventors: Brian C. Frank, Cedarburg, WI (US); Gerald W. Renderman, West Bend, WI (US); John P. Mason, Sussex, WI (US); Matthew S. Hill, Kitchener (CA); Chao G. Moua, Mequon, WI (US)

(21) Appl. No.: 18/754,890

(22) Filed: Jun. 26, 2024

(51) Int. Cl. G06F 30/27; G06F 30/12

(52) U.S. Cl. CPC G06F 30/27; G06F 30/12

(57) ABSTRACT

The present disclosure describes systems and methods for generating new base designs for industrial units. Embodiments include leveraging a General Artificial Intelligence (GAI) model to generate new base designs based on parameter values input by an administrator of an industrial design application. The GAI model generates new base designs generated based on the parameters, including the unit type, industry type, and installation location, according to some embodiments. The base designs are stored in a base design repository and provided to users of an industrial design application in response to requests for designs.

### RELATED APPLICATIONS

This U.S. Patent Application is related to co-pending U.S. Patent Application entitled “PROFILE-BASED PROMPT ENGINEERING FOR USER-SPECIFIC INDUSTRIAL AUTOMATION PROJECT CUSTOMIZATION,” Attorney Docket Number 2024P-025-US, filed concurrently, the contents of which are incorporated herein in their entirety for all purposes.

This U.S. Patent Application is related to co-pending U.S. Patent Application entitled “COMMON CONFIGURATION VALIDATION IN INDUSTRIAL DESIGN APPLICATIONS USING GENERATIVE ARTIFICIAL INTELLIGENCE,” Attorney Docket Number 2024P-026-US filed concurrently, the contents of which are incorporated herein in their entirety for all purposes.

This U.S. Patent Application is related to co-pending U.S. Patent Application entitled “UPDATING BASE DESIGNS IN INDUSTRIAL DESIGN APPLICATIONS USING GENERATIVE ARTIFICIAL INTELLIGENCE,” Attorney Docket Number 2024P-029-US, filed concurrently, the contents of which are incorporated herein in their entirety for all purposes.

### TECHNICAL FIELD

The disclosure generally relates to an intelligent pre-sale industrial design application, and more specifically to an industrial design application utilizing a Generative Artificial Intelligence (GAI) model, such as a Large Language Model (LLM) or Multi-Modal Model (MMM), to generate new base designs (e.g., for emerging markets) for a base design repository.

### BACKGROUND

In preparation for building, updating, or modifying industrial systems in a factory, a user may use an industrial design application to plan details, including selecting components (e.g., machines, controllers, cabinets, and the like), selecting configuration settings of the components, and designing layouts of the system. Once configured, the user can submit the design for quoting using the industrial design application.

The industrial design application stores designs for industrial units in a database of designs. The industrial design application may select designs from the database and provide them to users as initial designs for the industrial systems. When the industrial design application is servicing a customer in an emerging market (such as a specific country developing an automative industry), the administrators of the industrial design application may develop new designs to meet the particular needs of the emerging market. Developing new designs from scratch is a time-intensive and costly process, requiring a significant amount of creativity and expertise. Furthermore, it is challenging for administrators to stay on pace in the design development process when there are many rapidly developing industries.

### SUMMARY

The disclosure describes leveraging a GAI model to develop new base designs for a base design repository. The base design repository is a library of generic base designs provided to users of an industrial design application. Upon receiving generic base designs, users may customize the design, for example by selecting various options within the option packs of the generic base designs. When new base designs are developed for emerging markets, quality designs are developed quickly by leveraging the GAI model.

One example of a computer-implemented method for updating an industrial design database performed according to some embodiments includes receiving from an administrator of an industrial design application, via a user interface, a design request to generate a base design for an industrial unit, the design request including a plurality of parameter values. Corresponding parameters to the parameter values include a type of the industrial unit, an installation location, and an industry type. The method further includes generating a model prompt to elicit a response from a Generative Artificial Intelligence (GAI) model trained on a plurality of existing base designs associated with various types of industrial units, various industry types and various installation locations. The model prompt includes the plurality of parameter values and a request to generate a new base design for the industrial unit based on plurality of parameter values. The method further includes submitting the prompt to the GAI model. The method further includes receiving from the GAI model, in response to the prompt, the new base design generated by the GAI model based on the plurality of parameter values.

In some embodiments, the method further includes providing a review request to the administrator via the user interface. The review request includes the new base design, a first selectable option to approve the new base design, a revision query prompting the administrator to input a revision request for the new base design, and a second selectable option for the administrator to submit the revision request.

In some embodiments, the method further includes generating a revision prompt for the GAI model, the revision prompt including the revision input and metadata of the new base design. The method further includes submitting the revision prompt to the GAI model. The method further includes receiving, from the GAI model in response to the revision prompt, a revised generic base design. The method further includes providing, to the administrator via the user interface, an updated review request comprising the revised generic base design, the first selectable option, and the second selectable option.

The method further includes providing a review request to the administrator via the user interface. The review request includes: the new base design, a first selectable option to approve the new base design, a revision query prompting the administrator to input a revision request for the new base design, and a second selectable option for the administrator to submit the revision request. The method further includes receiving a selection of the first selectable option indicating an approval of the new base design. The method further includes adding, in response to the selection, the new base design to a base design repository. The base design repository stores a plurality of generic base designs for industrial units.

The method further includes receiving a request from a user of the industrial design application for a design for an industrial automation project. The method further includes providing to the user, in response to the request for a design, an initial layout of an industrial automation project, the initial layout including the new base design.

The method further includes providing the GAI model with static data during initial training, the static data including one or more of: industrial product literature associated with the various types of industrial units, industry standard data associated with the various industry types, and safety regulations data associated with the various installation locations.

The method further includes selecting an existing base design from the plurality of existing base designs based on the plurality of parameter values. The model prompt further includes metadata associated with the existing base design. The request to generate the new base design further includes a request to modify the metadata of the existing base design to achieve a design that meets constraints associated with the plurality of parameter values.

The method further includes receiving, from an administrator via a user interface of an industrial design application, an initial request for industrial design assistance. The method further includes providing to the administrator via the user interface, in response to the initial request, a design query prompting the administrator to input the parameter values. The receiving the design request from the administrator is in response to providing the design query to the administrator.

In some embodiments the design request to generate a base design for an industrial unit is a design request to generate a base design for a motor controller unit, a power distribution center, a factory line or other industrial automation equipment.

These and other features and aspects of various examples may be understood in view of the following detailed discussion and accompanying drawings.

### BRIEF DESCRIPTION OF THE DRAWINGS

FIG. 1 illustrates an industrial design generation system, according to some embodiments.

FIG. 2 illustrates a logical view of exemplary base design elements, according to some embodiments.

FIG. 3 illustrates a view of the cloud service of FIG. 1, according to some embodiments.

FIGS. 4A and 4B illustrate a method for generating new base designs, according to some embodiments.

FIG. 5 illustrates an operational scenario for the industrial design generation system of FIG. 1, according to some embodiments.

FIGS. 6A and 6B illustrate graphical user interfaces, according to some embodiments.

FIG. 7 illustrates prompt templates, according to some embodiments.

FIG. 8 illustrates an exemplary computing system, according to some embodiments.

### DETAILED DESCRIPTION

This disclosure relates to the use of a Generative Artificial Intelligence (GAI) model, (e.g., a Large Language Model (LLM) or Multi-Modal Model (MMM)), to generate base designs for an industrial design application. The industrial design application assists users in the design and procurement of industrial automation projects. Industrial automation projects may include one or more industrial automation devices. Individual industrial automation devices may include, for example, drives, controllers, conveyors, and the like. Combinations of industrial automation devices to create an industrial automation project may include, for example, Motor Control Centers (MCCs) that may include a combination of industrial automation devices including industrial automation drives, industrial automation controllers, a cabinet for the industrial automation devices, and the like. Industrial automation projects may also be designs for other industrial systems such as power distribution centers, factory systems, and control systems, for example. An industrial automation project for an entire factory may include all industrial automation devices needed to operate a factory. The industrial design application quickly provides users with unique designs for industrial automation projects and provides the users with the ability to easily customize the designs. The industrial design application may be utilized in the pre-sale phase of industrial automation projects. In the pre-sale phase, the user accesses the industrial design application to design the industrial automation project and request a quote.

The industrial design application includes a base design repository storing generic base designs, which are designs for fully functional industrial units. The generic base designs are selected and provided to customers in response to requests for designs of industrial automation projects. Administrators of the industrial design application may sometimes develop new generic base designs to incorporate advances in technology and to accommodate emerging markets (e.g., a developing industry in a specific country). Once an administrator develops a new generic base design, the new generic base design is stored in the base design repository and provided to customers (e.g., a customer in an emerging market) in response to requests for designs.

Developing new base designs is a costly process. Design engineers generally have extensive experience and need in-depth knowledge of existing base designs. Further, study of specifications and other constraints (e.g., industry laws, local regulations, and the like) related to standards for the emerging market location and industry type takes time. Furthermore, the creation of new base designs involves creativity since design engineers create designs that serve the unique needs of customers in emerging markets. In an environment in which many countries are developing new industries (e.g., oil and gas, automotive, and food and beverage) there may be a high demand for the creation of new generic base design to accommodate the unique needs of each developing industry. Furthermore, even in existing markets, customers may request new generic base designs that align with current methodologies and preferences. When generic base designs are not developed rapidly enough, customers face challenges in trying to utilize existing generic base designs that are not uniquely suited to their needs.

To address the above-described issues, an improved industrial design application is disclosed that leverages a General Artificial Intelligence (GAI) model to create new base designs for a base design repository of the industrial design application. A design engineer may provide a few parameters for the new generic base design (e.g., unit type, industry type, installation location, and additional design requests). The disclosed system utilizes the provided parameters to craft a prompt to coax the GAI model into generating a new generic base design uniquely suited for the new market. The GAI model generates new generic base designs based on the parameters in the prompt. The GAI model is trained on many existing generic base designs, including industrial information associated with various industry types and installation locations. Based on the training and the parameters in the prompt, the GAI model generates a new generic base design that is suited to the unique needs of an emerging market. Once the design engineer receives the new generic base design, the design engineer may approve the design for inclusion in the base design repository. If the design engineer is not satisfied with the design, the engineer may make further requests for the GAI model modify to the design.

Leveraging the GAI model greatly increases efficiency for engineers developing new base designs. In existing environments, the process of creating a new base design is far from instantaneous. Design engineers often spend a significant amount of time researching information related to the emerging market (including industrial information related to the location and industry type), and the design process itself may take days or weeks. When there is a backlog of new units to be designed, it may even take months to complete a design after receiving a request from a customer. In the system disclosed herein, a design engineer may instantaneously arrive at a new base design by entering just a few parameters. The industrial design application crafts the engineer's parameters into a prompt for the GAI model, which may generate a design uniquely suited to the needs of an emerging market, based on learned associations with existing base designs for similar industry types and installation locations. Furthermore, a design engineer may enter a miscellaneous request for the design (e.g., “optimize the design for cost”) for inclusion in the prompt for the GAI model. The ability to enter such a request for consideration by the GAI model provides a high degree of flexibility in the design process. Engineers may quickly enter specific requests to meet the unique needs of the emerging market, and almost instantaneously receive a design tailored to the specific request.

Additionally, resource usage may be reduced using the disclosed systems. For example, common selections for customers in similar industries and locations do not need to be individually determined and stored. Furthermore, the disclosed systems may reduce operational costs, since the GAI model may accurately make associations with related industries and installation locations in the design process, reducing the need for database maintenance and data analysis processing operations.

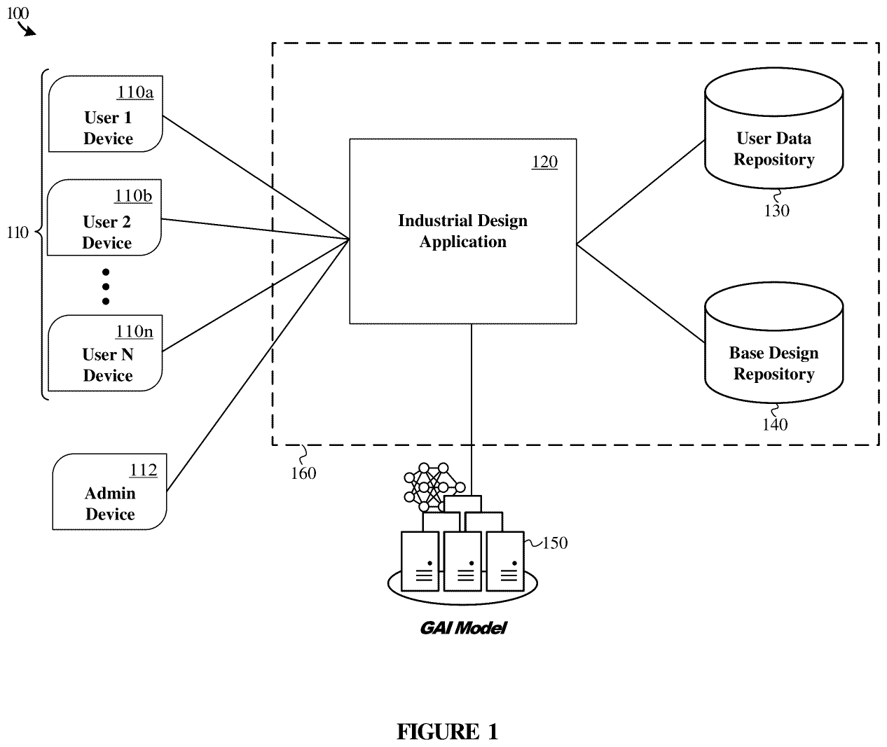

FIG. 1 illustrates system 100 according to some embodiments. System 100 includes user devices 110, admin device 112, cloud platform 160, and GAI model 150. While specific elements of system 100 are shown for ease of description, system 100 may include more or fewer of each described component as well as other components not described for simplicity.

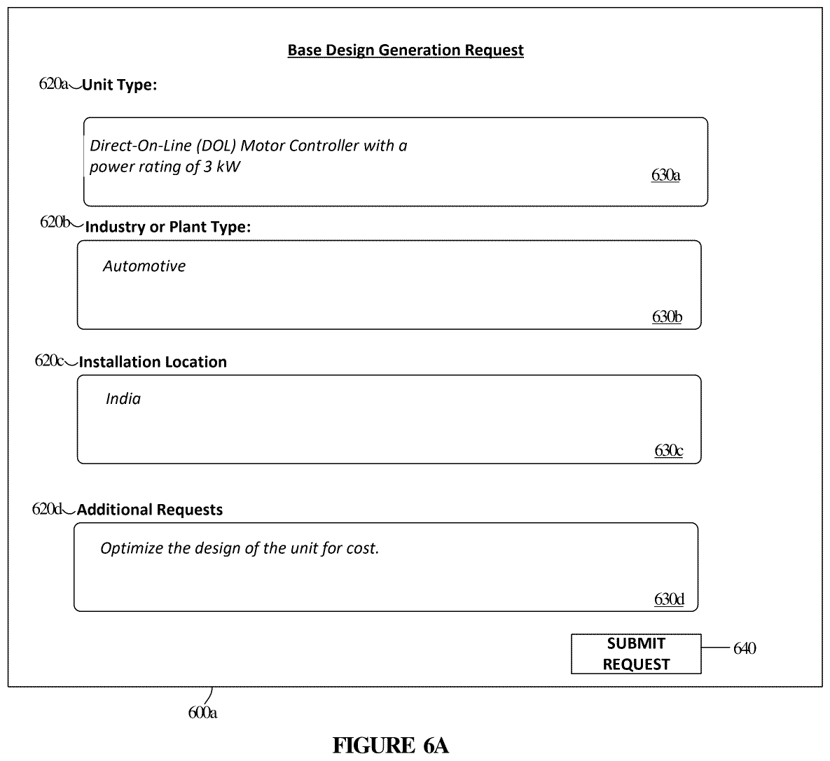

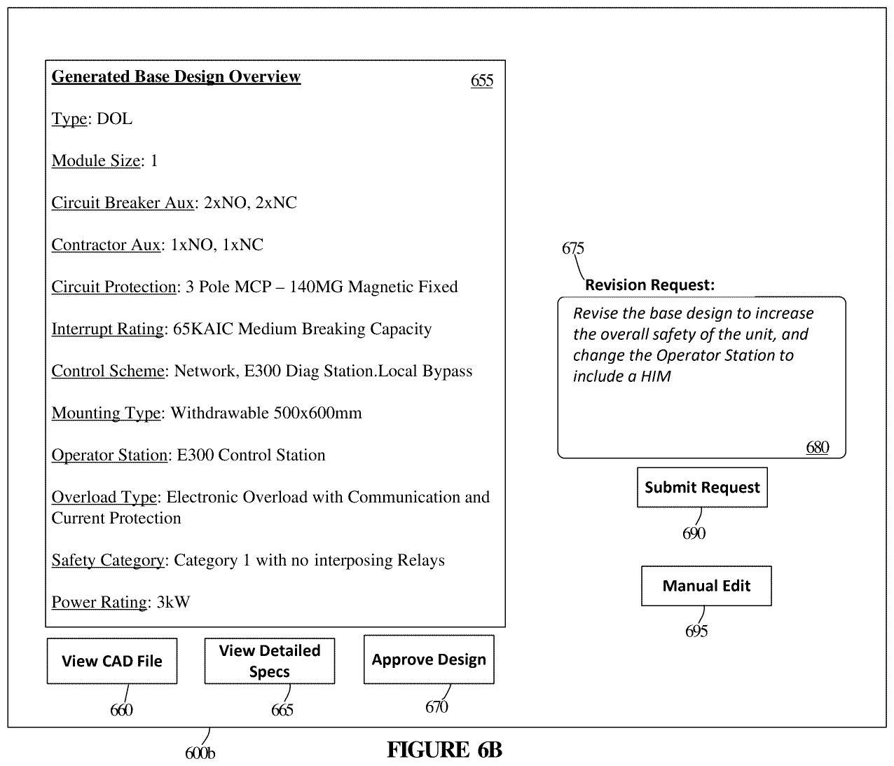

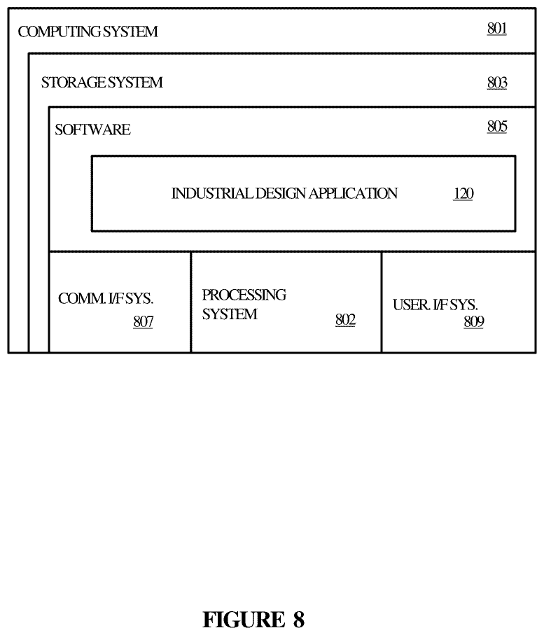

User devices 110 include user 1 device 110a, user 2 device 110b, and user N device 110n. While three user devices are shown in FIG. 1 for simplicity, system 100 may include any number N of user devices 110. User devices 110 may include personal computers, laptops, mobile devices such as smartphones or tablets, or any other similar device capable of interfacing with industrial design application 120. Users may access industrial design application 120 on user devices 110. Specifically, users may log in to a user account on a web browser on the user device to access industrial design application 120. In some embodiments, the users may open an application program on user device 110 to access industrial design application 120. In either case, industrial design application 120 provides a user interface to display to the user on user device 110. Exemplary user interfaces 600 are shown in FIGS. 6A-6D. User devices 110 may be computing device 801 described with respect to FIG. 8.

A user may interact with the user interface on user device 110 to make a request for a design of an industrial automation project. Such a request may be made in the pre-sale phase of the industrial automation project. The industrial automation project may include one or more industrial automation devices, including a layout of physical components for installation, for example, on a factory floor. In the pre-sale phase, the user may design and configure the industrial automation project using the user interface on user device 110. Once the user is satisfied with the industrial automation project design, the user may request a quote for the designed industrial automation project (i.e., each of the configured industrial automation devices in the industrial automation project).

To make the request for the design, the user may input parameters of the industrial automation project in the user interface of user device 110. In some embodiments, the parameters include the relevant industry (e.g., “Automotive” or “Food/Beverage”) and the installation location (e.g., country, city, region, or the like) in which the industrial automation project is to be implemented. Parameters may also include a load list, setting forth the required functionality of the industrial automation project. When the industrial automation project is an MCC, the load list may be a motor-load list, in which the user inputs the types of motor controllers (e.g., Direct Online Starter (DOL), Variable Frequency Drive (VFD), etc.) required in the MCC, as well as other relevant parameters such as the required power rating for each motor controller. Once the user has input the parameters, the user may submit the request for the design of the industrial automation project via the user interface of user device 110.

Generated designs for the industrial automation project are provided to users via the user interfaces of user devices 110, in response to design requests. The generated design includes one or more customized base designs and an arrangement of the customized base designs including physical placement, connections, and the like when appropriate. The customization of base designs is discussed in further detail below. Each customized base design is a design for a fully functional industrial unit, customized by GAI model 150 based on learned user preferences. A fully functional industrial unit may be a single industrial automation device (e.g., a programmable logic controller, a drive, or the like) or it may be a combination of industrial automation devices arranged into a common configuration (e.g., a motor control center (MCC)). The generated design may include a complete layout for a set of customized base designs. A generated design for an MCC is shown, for example, in FIG. 6B, which includes an arrangement of motor controllers in a series of columns. Once the user receives the design, the user may make modifications to the generated design, as discussed in detail in FIGS. 6C and 6D below. For example, the user may modify configuration options, remove or add base designs for one or more industrial units, or the like. Once the user is satisfied with the design of the industrial automation project, the user may submit the finalized project. The submission of the finalized project may include, for example, a request for a quote. Users may also interact with the user interfaces of user devices 110 to perform other tasks such as submitting feedback, viewing help topics, reporting bugs, requesting live customer assistance, and viewing product catalogues, for example.

Admin device 112 is used by administrators to perform administrative tasks in industrial design application 120. While one admin device 112 is shown in FIG. 1 for simplicity, system 100 may include multiple admin devices 112 utilized by multiple administrators of industrial design application 120. Admin devices 112 may include personal computers, laptops, mobile devices such as smartphones or tablets, or any other similar device. Administrators may access industrial design application 120 via user interfaces on admin devices 112. The user interfaces may be viewed, for example, in web browsers accessing industrial design application 120 remotely, in specialized locally installed applications that access industrial design application 120 remotely, or directly in a locally installed implementation of industrial design application 120. Functions performed by administrators may include updating software of industrial design application 120, maintaining generic base designs in base design repository 140, and the like. Admin devices 112 may be computing device 801 described with respect to FIG. 8.

An administrator such as an industrial design engineer performs design functions for industrial design application 120 via a user interface of admin device 112 (for example, user interfaces 600a and 600b of FIGS. 6A and 6B). The administrator may request GAI model 150 assistance to generate a new generic base design for base design repository 140. In response to a request for design assistance the industrial design application may provide a design query to the administrator via the user interface, such as user interface 600a of FIG. 6A. The administrator may input the parameters in the user interface and submit it. Subsequently, the administrator may view details of a new base design (generated by GAI model 150 based on the administrator's parameters) on the user interface, such as user interface 600b of FIG. 6B. The administrator may approve the design or request further revisions, as discussed in greater detail in method 400 below.

Cloud platform 160 includes industrial design application 120, user data repository 130, and base design repository 140. Cloud platform 160 may optionally include Generative Artificial Intelligence (GAI) model 150 in some embodiments. Cloud platform 160 operates from servers which may be located in data centers, distributed in various geographic locations, and the like. Various software components of cloud platform 160 may have multiple instances in different geographic locations for redundancy and speed.

Industrial design application 120 includes software operating from servers in the cloud platform 160. Industrial design application 120 may be a web-based application that assists users in the design of industrial automation projects. Industrial design application 120 may be utilized in the pre-sale phase of industrial automation systems. In the pre-sale phase, industrial design application 120 assists users in designing and configuring the industrial automation projects, and to provide quotes to the users for the projects. Industrial design application 120 generates a layout of industrial units in industrial systems based on parameters defined by the user. In the process of assisting in the design of an MCC, industrial design application 120 may generate a lineup of motor controllers and other components (such as circuit breakers and power buses) to meet the parameters of a user's design request. Industrial design application 120 interacts with user devices 110, admin devices 112, user data repository 130, base design repository 140, and GAI model 150 to perform various functions as discussed below. Industrial design application 120 may be computer software implemented on one or more servers and/or in a cloud-based environment. Industrial design application 120 may be implemented in memory on a server such as, for example, computing device 801 as described with respect to FIG. 8.

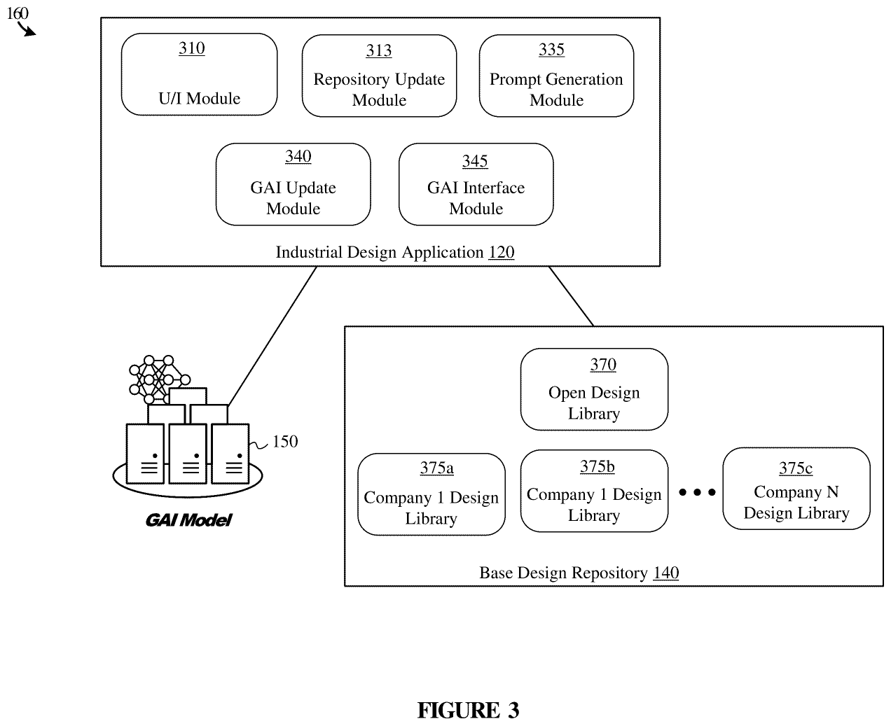

Industrial design application 120 receives requests from users for designs of industrial automation projects. Such requests may include parameters defined by users, as discussed above. Based on the parameters in the user request, industrial design application 120 selects generic base designs from base design repository 140 to include in an initial design of the industrial automation project. For example, in the case in which the request is for the design of an MCC, industrial design application 120 selects a generic base design for a motor controller for each load included in the motor-load list of the user's request. The selection of a generic base design is based on the type of motor controller requested (e.g., VFD) as well as other stated parameters (e.g., power ratings) in the parameters. Industrial design application 120 generates a layout for the industrial automation project including all the generic base designs selected. However, it is noted that industrial design application 120 may also prompt GAI model 150 to generate customized base designs before generating the layout, as discussed in further detail in related applications incorporated by reference above. Once the layout for the industrial automation project is generated, industrial design application 120 displays the layout to the user via user interface of user device 110. Industrial design application 120 may receive design selections from the user, where the design selections are modifications of industrial design application 120 made by the user in the user interface of user device 110. Industrial design application 120 receives requests from administrators to generate new generic base designs. In response to the requests, industrial design application 120 leverages GAI model 150 to generate new base designs, as discussed in greater detail in method 400 below. Furthermore, FIG. 3 includes additional details of the functionalities performed by industrial design application 120.

User data repository 130 is a database storing information about each user of industrial design application 120. In some embodiments, the user data repository may include basic information about each user such as login information, contact information, and the user's organization or company. The user data repository may also include historical user data including previous industrial design configurations submitted by the user, and previous products purchased by the user. This historical user data may be provided to GAI model 150 for training, as discussed in further detail in method 400 below. The user data in user data repository 130 be stored in memory of cloud platform 160. User data repository 130 may be computing device 801.

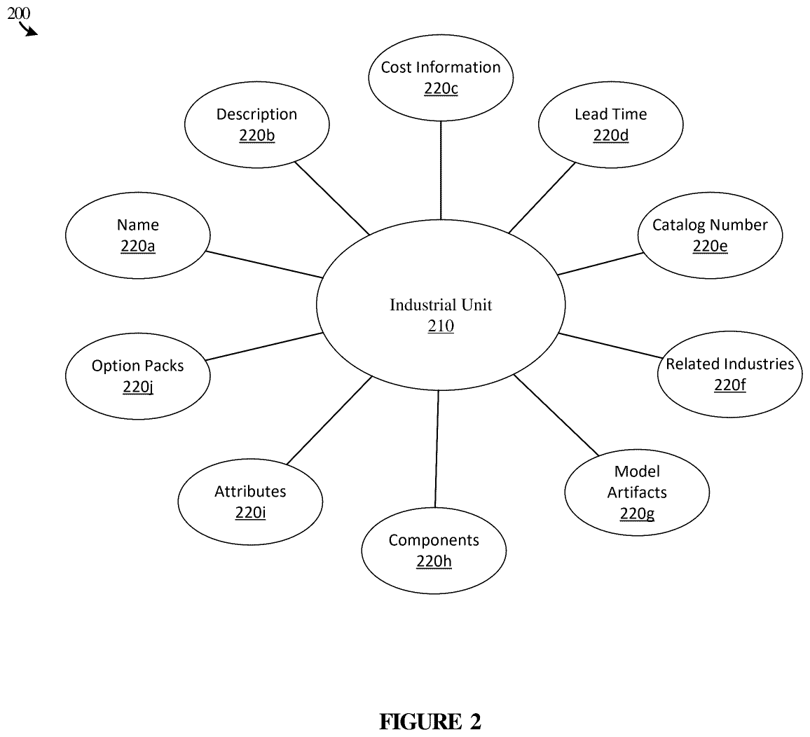

Base design repository 140 is a database of generic base designs of industrial units. Each generic base design in base design repository 140 includes a generic design configuration for a fully functional industrial unit. The generic base designs in base design repository 140 may be base design 200 of FIG. 2. Metadata for each generic base design, for example the metadata 220 of FIG. 2, is stored in the base design repository 140. The metadata includes detailed information defining a fully functional industrial unit, as discussed further in FIG. 2 below. The metadata may include option packs for the industrial units. Option packs include various options for configurable aspects of the industrial unit (e.g., option packs 220j of FIG. 2). For example, a base design for a VFD could include an “Operator Station” option pack. A user may thus choose between different types of operator stations, such as an operator station having a Human Interface Module (HIM), or an operator station having a combination of a HIM and indicator lights. Each option pack may include a default selection. Generic base designs in base design repository 140 may be stored in a server or a memory storage device of cloud platform 160.

Each generic base design in base design repository 140 may be associated with specific industry types and locations. When a new industry is developing in a country (i.e., an emerging market), base design repository 140 may not include base designs that are tailored to the unique needs of the emerging market. An administrator may request GAI assistance to generate new base designs for base design repository 140 to meet the needs of the emerging market, as discussed in greater detail in method 400 below.

GAI model 150 is a generative artificial intelligence model trained to perform industrial design tasks. GAI model 150 may include a system of transformer-based neural networks with a vast number of parameters (e.g., weights and balances). The parameters are adjusted during training for learning including industrial data and common selections among users of the industrial design application 120. The training of GAI model 150 is discussed in further detail in method 400 below. The GAI model may be a large language model (LLM) trained on a vast amount of textual data. An LLM is capable of processing textual inputs to generate textual outputs. In some embodiments, GAI model 150 is a Multi-Modal Model (MMM). An MMM may be trained on a vast amount of various types of data, including, for example, textual data, video, audio, images, 3-D renderings, CAD files, and other various forms of media. An MMM may be capable of processing inputs and generating outputs in each of these formats. GAI model 150 may be implemented on a computing device (e.g., computing device 801 of FIG. 8), typically in a cloud-based environment due to the processing and memory resources needed to support GAI model 150. However, on-premises implementations are within the scope of this disclosure. Further, GAI model 150 is depicted outside of cloud platform 160. However, in some embodiments, GAI model 150 may be hosted within cloud platform 160, for example, as an enterprise-specific instance.

An administrator of the industrial design application 120 may leverage the GAI model 150 to generate new base designs, as discussed in the method 400 below. It is noted that the industrial design application 120 may leverage the GAI model to perform other industrial design tasks discussed in related applications incorporated by reference above.

GAI models (also known as foundation models) are models trained to generate new data based on a training dataset. GAI models as used herein include large-scale generative artificial intelligence (AI) models trained on massive quantities of diverse, unlabeled data. The GAI models learn using self-supervised, semi-supervised, or unsupervised techniques. GAI models perform many downstream tasks based on capturing general knowledge, semantic representations, and patterns and regularities in the training data. In some embodiments, such as embodiments included herein, a GAI model may be fine-tuned for specific downstream tasks. GAI models include BERT (Bidirectional Encoder Representations from Transformers) and ResNet (Residual Neural Network). GAI models may be based on any relevant architecture, including, for example, generative adversarial networks (GANs), variational auto-encoders (VAEs), and transformer models, including multimodal transformer models. Depending on the type of input accepted and output provided, GAI models may be multimodal or unimodal.

Multimodal models are a class of GAI models that accept multimodal data including text, image, video, and audio data. Multimodal models may leverage techniques like attention mechanisms and shared encoders to fuse information from different modalities and create joint representations. Learning joint representations across different modalities enables multimodal models to generate multimodal outputs that are coherent, diverse, expressive, and contextually rich. For example, multimodal models can generate a caption or textual description of a given image by extracting visual features using an image encoder, then feeding the visual features to a language decoder to generate a descriptive caption. Similarly, multimodal models can generate an image based on a text description (or, in some scenarios, a spoken description transcribed by a speech-to-text engine). Multimodal models work in a similar fashion with video—generating a text description of the video or generating video based on a text description.

Multimodal models include visual-language foundation models, such as CLIP (Contrastive Language-Image Pre-training), ALIGN (A Large-scale ImaGe and Noisy-text embedding), and ViLBERT (Visual-and-Language BERT), for computer vision tasks. Examples of visual multimodal or foundation models include DALL-E, DALL-E 2, Flamingo, Florence, and NOOR. Types of multimodal models may be broadly classified as or include cross-modal models, multimodal fusion models, and audio-visual models, depending on the particular characteristics or usage of the model.

Large language models (LLMs) are a type of GAI model that process and generate natural language text. These models are trained on massive amounts of textual data. LLMs learn to generate relevant responses given a prompt or input text. The responses are coherent and contextually relevant to the given prompt. LLMs understand and generate sophisticated language based on their training. LLMs capture intricate patterns, semantics, and contextual dependencies in textual data. In some cases, LLMs may be used in multimodel models. For example, the LLM intelligence is used to combine images and audio input with textual input to generate multimodal output. Types of LLMs include language generation models, language understanding models, and transformer models.

Transformer models, including transformer-type foundation models and transformer-type LLMs, are a class of deep learning models used in natural language processing (NLP). Transformer models are based on a neural network architecture which uses self-attention mechanisms to process input data and capture contextual relationships between words in a sentence or text passage. Transformer models weigh the importance of different words in a sequence, allowing them to capture long-range dependencies and relationships between words. GPT (Generative Pre-trained Transformer) models, BERT (Bidirectional Encoder Representations from Transformer) models, ERNIE (Enhanced Representation through kNowledge IntEgration) models, T5 (Text-to-Text Transfer Transformer), and XLNet models are types of transformer models which have been pretrained on large amounts of text data using a self-supervised learning technique called masked language modeling. For example, large language models, such as ChatGPT and its brethren, have been pretrained on an immense amount of data across virtually every domain of the arts and sciences. This pretraining allows the models to learn a rich representation of language that can be fine-tuned for specific NLP tasks, such as text generation, language translation, or sentiment analysis. Moreover, these models have demonstrated emergent capabilities in generating responses that are creative, open-ended, and unpredictable.

In practice, an administrator may access industrial design application 120 by logging into an administrator account on admin device 112. The administrator may then send a request to industrial design application 120 to generate a new baes design with GAI model 150 assistance. In response, industrial design application 120 provides a design query to admin device 112. The design query prompts the administrator to input parameters for the new generic base design, as shown for example in user interface 600a of FIG. 6A. The administrator may input the parameters and submit them to industrial design application 120.

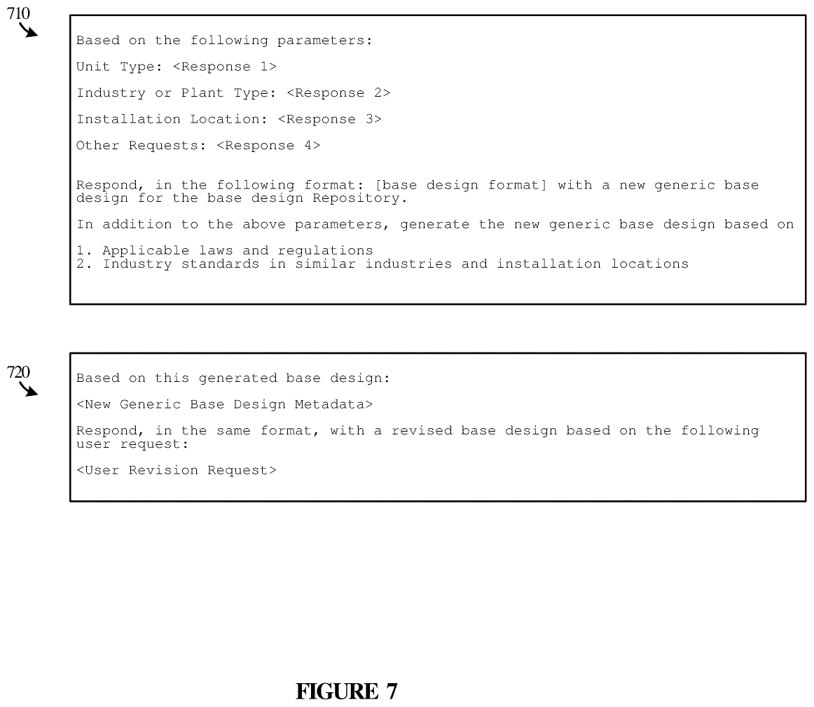

Once industrial design application 120 receives the parameters, it generates a prompt for GAI model 150 including the parameters (e.g., unit type, industry type, install location, and additional requests). Industrial design application 120 may utilize a prompt template such as prompt template 710 of FIG. 7 to generate the prompt. Industrial design application 120 submits the prompt to GAI model 150, and GAI model 150 responds with a new generic base design generated based on the parameters in the request. Details of the new generic base design may be provided to the administrator via a user interface such as user interface 600b in FIG. 6B. The administrator may then review the new generic base design and approve the generic base design. If the administrator indicates approval of the generic base design, the new generic base design is added to base design repository 140. Alternatively, the administrator may desire to make alterations to the generic base design. To do so, the administrator may type in a request indicating which aspects of the design should be updated and submit the request for revision. When industrial design application 120 receives a revision request, it generates a new prompt for GAI model 150. The new prompt includes the revision request and may be generated, for example, based on prompt template 720 of FIG. 7. The process of revising the new base design may be performed iteratively until the administrator is satisfied with the design, as discussed in method 400 below.

FIG. 2 illustrates a schematic view of base design 200 according to some embodiments. Base design 200 contains detailed design data about a specific industrial unit 210. Base design 200 of FIG. 2 may be representative of the generic base designs stored in base design repository 140 of FIG. 1. Base design 200 may also be representative of the customized base designs provided to users, as described herein. Base design 200 includes industrial unit 210 and metadata 220. Metadata 220 includes name 220a, description 220b, cost information 220c, lead time 220d, catalog number 220e, related industries 220f, model artifacts 220g, components information 220h, attributes 220i, and option packs 220j. Metadata 220 may be representative of metadata in base design 200, however base design 200 may include additional metadata 220 or less metadata 220 without departing from the scope of the present disclosure.

Industrial unit 210 of base design 200 represents a design for a fully functional industrial unit 210. Industrial unit 210 may be represented in a CAD file or blueprint stored in base design repository 140. In the context of an MCC, industrial unit 210 may be, for example, an industrial automation device such as a circuit breaker, a drive, or any other industrial unit 210 included in an MCC. Industrial unit 210 may include sub-components, in some examples. For example, a Direct On-Line (DOL) motor controller may include an arrangement of auxiliary contacts. In addition to the sub-components, the DOL may include other parameters including, for example, a control scheme, a mounting type, an operator station, a specific overload type, and a safety category. I Industrial unit may also be a broader unit such as a cabinet of an MCC, with an arrangement of various motor controllers and other components such as power buses within the cabinet. In an even broader sense, industrial unit 210 may be a fully functional MCC, with an arrangement of all motor controllers and other necessary industrial automation devices, arranged with all relevant connections, in multiple cabinets. As such, base design 200 may define various levels of designs, from individual industrial automation devices (e.g., circuit breakers) to an entire factory of industrial automation devices including their connections and relationships, and everything in between (e.g., an MCC). Base design 200 may be provided to users in response to requests from users to generate an industrial automation project. For example, if a user makes a request for a design of an MCC, industrial design application 120 may generate a design for an MCC by selecting several base designs 200, requesting customized base designs from GAI model 150, and generating a layout of the customized base designs to create a fully functional MCC design customized for the specific user. Alternatively, base design repository 140 may include a base design for an MCC that can be customized by GAI model 150 to meet the needs of the user's request based on the generated prompt. In either case, a user-specific customized design for a fully functional MCC may be generated. A user may further modify the design once the user views the design in industrial design application 120 by changing various selectable options within the design.

Metadata 220 collectively refers to metadata 220a-220j of base design 200. Metadata 220 includes detailed information about industrial unit 210, which may be stored in one or more taxonomy files. The taxonomy files may include spreadsheets, CAD files, electrical schematic blueprints, and other diagrams and file types for storing the information about industrial unit 210. Specific examples of metadata 220 are provided, but any variation may be used to describe industrial unit 210 without departing from the scope of the present disclosure.

Metadata 220 may include name 220a of industrial unit 210. Name 220a may include, for example, the unit type (e.g., VFD) in addition to an identifying model number. In other examples, a model number, a type of device, or any other name may be used.

Metadata 220 may include description 220b of industrial unit 210. Description 220b may include high-level information about industrial unit 210, as shown, for example, in the high-level overview of configuration list 655 of FIG. 6C. Description 220b may also include detailed industrial specifications for industrial unit 210 in some embodiments.

Metadata 220 may include cost information 220c indicating the cost of industrial unit 210, including various price changes for selections of different selectable options, for example, within option packs 220j discussed below.

Metadata 220 may include lead time 220d, the time-interval between the purchase and delivery of industrial unit 210.

Metadata 220 may include catalog numbers 220e associated with industrial unit 210. Catalog numbers 220e may identify industrial unit 210 or sub-components of industrial unit 210. Catalog numbers 220e may be used for organizing industrial units 210 in a product catalog, for example.

Metadata 220 may include related industries 220f, which may indicate which industries industrial unit 210 is suitable for (e.g., the metals industry or the food and beverage industry).

Metadata 220 may include model artifacts 220g. Model artifacts 220g may include models of industrial unit 210 and may include, for example, CAD files, electrical schematics, single-line diagrams, and mechanical models of industrial unit 210. Model artifacts 220g may further include a layout of industrial unit 210 illustrating, for example, how industrial unit 210 is laid out in a grid.

Metadata 220 may include components information 220h, which may include information about sub-components included in industrial unit 210. For example, some of the sub-components of a motor controller may include control circuitry, an operator station, a circuit breaker, and a housing.

Metadata 220 may include attributes 220i, which may include information about the capabilities of industrial unit 210, such as maximum power ratings.

Metadata 220 may include option packs 220j. There may be one or more option packs 220j, where users can select various options within each option pack 220j. An example option pack 220j is represented in FIG. 8D. Alternatively, when base design 200 is a design for an MCC, for example, the option pack 220j may include information about various substitutable components (e.g., motor controller models that are substitutable for the motor controller models included in base design 200). Each option pack 220j may have a default selection. In generating customized base designs, GAI model 150 may make alternate selections of options within option packs 220j based on learned user preferences.

FIG. 3 illustrates cloud platform 160 according to some embodiments. Cloud platform 160 includes industrial design application 120, user data repository 130, base design repository 140, and GAI model 150. Cloud platform 160 may be implemented on servers in a datacenter, distributed geographically, and/or the like. Note that GAI model 150 is depicted as part of cloud platform 160 in FIG. 3, however this is an optional configuration as discussed above with respect to FIG. 1. GAI model 150 may be hosted within cloud platform 160 or externally without departing from the scope of this disclosure.

User data repository 130 may store information about each user of the industrial design application 120. User data repository 130 includes basic information about each user including login information, contact information, and the user's organization or company. User data repository 130 may also include historical user data including previous industrial design configurations submitted by the user, and previous products purchased by the user. The historical data in user data repository 130 may be used to train GAI model 150 to learn user-specific preferences for each user, as well as common industrial preferences.

Base design repository 140 is a database of generic base designs. In some embodiments base design repository 140 may include open design library 370. Open design library 370 is a library of generic base designs that may be provided to any user of industrial design application 120 regardless of company affiliation. Base design repository 140 also contains company specific design libraries including Company 1 Design Library 375a, Company 2 Design Library 375b, and Company N Design library 375n (collectively “Company Design Libraries 375” for N number of companies). For example, Company 1 Design Library 375a contains generic base designs specific to Company 1, Company 2 Design Library 375b contains generic base designs specific to Company 2, and Company N Design Library 375n contains generic base designs specific to Company N (for any number N of companies that have specific design libraries). Storing company specific generic base designs allows industrial design application 120 to provide company specific customization to users of industrial design application 120. For example, a specific company may design preferences that are not commonly practiced by designers in other organizations. Furthermore, this arrangement allows for the protection of intellectual property such as trade secrets, as a company specific generic base design will not be provided to users who are not affiliated with the company.

Base design repository 140 may include any number of generic base designs. For example, in various embodiments, base design repository 140 may include on the order of hundreds or thousands of generic base designs. Each generic base design is stored either in Open Design Library 370 or one of Company Design Libraries 375. The generic base designs may be base design 200 of FIG. 2. Generic base designs are designs of fully functioning industrial units (e.g., Industrial Unit 210 described in detail with respect to FIG. 2) which may be included in an industrial automation project. Each generic base design may include an arrangement of sub-components including control components, operator interface components, and mounting components. Taxonomy files (e.g., metadata 220 of FIG. 2) associated with each base design may include details about the base design including cost information, bill of materials (BOMS) for the base design, and option packs. In the context of an MCC, a base design may be a power component, or a motor control unit tailored for a specific application. For example, a base design may be motor control unit tailored for a specific type of pump, conveyor, or mixer in an industrial environment. Each generic base design in base design repository 140 is a starting point for an industrial unit in a user's industrial automation project. Specifically, each generic base design includes a default configuration including default selections for configurable attributes, which users may modify in a user interface of industrial design application 120.

Base design repository 140 may include both GAI-generated generic base designs and generic base designs created by engineers without the GAI assistance. Some of the generic base designs may be designed by an engineering team to be tailored to a specific application. The generic base designs that are generated by GAI model 150 may undergo a review process by administrators or engineers before industrial design application 120 adds them to base design repository 140. User interface 600b of FIG. 6B, for example, shows a review request screen for an administrator to review the details of a GAI-generated generic base design. The generic base designs may be designed based on components, safety standards, industry standards, and applicable laws and regulations. It is noted that it is not feasible for any individual to keep abreast of all relevant industrial information, due to the vast amount of available industrial information. As such, GAI model 150 is trained on a vast amount of industrial information and is adapted to create optimized base designs for base design repository 140 based on the training and the parameters of a request input by engineers (for example, in user interface 600a of FIG. 6A).

GAI model 150 is a large artificial intelligence model trained to perform industrial design tasks for industrial design application 120. GAI model 150 may be an LLM or an MMM as discussed above. GAI model 150 may include multi-layered transformer architecture with many parameters (e.g., weights and biases) encoding information. GAI model 150 may be created by training a base generative model to perform industrial design functions. Such a base generative model may be licensed and hosted by a third party. Alternatively, the base generative model may be purchased or provided as an open-source model. Base generative models have generally been pre-trained on a vast amount of data. However, even though a base generative model may be pre-trained, it is generally not specifically trained to perform industrial design tasks. As such, initial training to perform industrial design functions may be performed to fine-tune the model to perform industrial design tasks. After the initial training, the model may be further trained to provide user-specific customizations. The training process for GAI model 150 is discussed in greater detail below.

As discussed in detail in method 400 below, GAI model 150 receives prompts from industrial design application 120 to generate new base designs and generates new base designs based on the parameters in the prompt. Prompts for GAI Model 150 may be generated by Prompt Generation Module 335 of industrial design application 120, as discussed below.

While GAI model 150 is described here as generating new base designs, it is noted that GAI model 150 may also perform other industrial design tasks. For example, GAI model 150 may be trained to generate user-specific customized base designs, to review user selections, and to update the generic base designs and option packs for generic base designs. These functions are described in greater detail in related applications incorporated by reference above.

Industrial design application 120 is a web-based application used to design industrial systems in the pre-sale phase of industrial automation projects, as discussed in FIG. 1 above. Industrial design application 120 interfaces with user data repository 130, base design repository 140 GAI model 150, and user devices 110 (not shown in FIG. 3, see FIG. 1). Industrial design application 120 includes a User Interface (U/I) Module 310, Repository Update Module 313, Prompt Generation Module 335, GAI Update Module 340, and GAI Interface Module 345. Further, while these modules are depicted to describe the generation of design layouts of industrial design application 120, the functionalities described may be incorporated into more or fewer components, software components, hardware components, firmware components, or a combination without departing from the scope and spirit of the present disclosure. Each of the modules is discussed in turn below.

User Interface (U/I) Module 310 interfaces with user devices 110 and admin devices 112 to render displays and receive inputs and requests. U/I Module 310 sends information for rendering a user display (such as user interfaces 600a, 600b of FIGS. 6A and 6B) on admin devices 112. U/I Module 310 may provide the administrator with a design query prompting the administrator to input parameter values for a new generic base design (as shown in user interface 600a of FIG. 6A). U/I module 310 may receive a submission of the parameters input by the administrator, as demonstrated by submission button 640 in FIG. 6A.

U/I module 310 may also provide the administrator with a user display for reviewing new base designs, as shown for example in user interface 600b of FIG. 6B. U/I module 310 may receive an approval of the new base design (for example, by the administrator selecting button 670 of FIG. 6B) or may receive a request from the administrator to revise the new base design (for example, by the administrator selecting button 690 of FIG. 6B).

U/I Module 310 also transmits information for rendering the user display on user devices 110. U/I Module 310 receives design selections and other inputs from users for designs of industrial automation projects (for example: requests for quotes, process requests for customer assistance, and process customer feedback comments). U/I Module 310 may also receive a request for a design for an industrial automation project from users, where the request for the design includes several user-selected parameters. In the case of an MCC, the user request may include a motor-load list, in addition to the industry type and installation location for the MCC.

Repository Update Module 313 adds new base designs to the base design repository 140. Repository Update Module 313 may add the new base design to base design repository 140 once the administrator approves the new design, for example, by clicking button 670 of FIG. 6B. Repository Update Module 313 may also create new folders or file locations in base design repository 140 in some embodiments. For example, when the new design is for an emerging market, base design repository 140 may not include a file location for base designs in the designated industry type and installation location. In such cases, Repository Update Module 313 may update base design repository 140 to include a file location with an associated industry type and installation market for emerging market.

Prompt Generation Module 335 generates prompts for GAI model 150. Prompt Generation Module 335 uses prompt templates, such as prompt templates 710, 720 of FIG. 7, to generate the prompt. Prompt templates 710, 720 may include a combination of text and placeholders. Various prompt templates may be stored in a memory storage of Prompt Generation Module 335, each prompt template being associated with a specific task for GAI model 150 (e.g., review of design selections, base design updates, base design customization, etc.). During prompt generation, Prompt Generation Module 335 selects an appropriate prompt template from the memory storage. For example, when U/I Module 310 receives a request from an administrator for a new base design (e.g., via user interface 600a of FIG. 6A) Prompt Generation Module 335 selects prompt template 710 of FIG. 7 for prompt generation. In another scenario, when U/I Module 310 receives a request from an administrator for a revision of the new base design (for example, via user interface 600b of FIG. 6B) Prompt Generation Module 335 selects prompt template 720 of FIG. 7 for prompt generation.

Prompt Generation Module 335 may select a design generation prompt template, such as prompt template 710 of FIG. 7, when U/I Module 310 receives a request for a new design of a base design (for example, via user interface 600a of FIG. 6A). Prompt Generation Module 335 incorporates the parameter values of the administrator's request (e.g., the unit type, industry type, installation location, and additional requests) into a prompt, for example, by inserting the parameter values into placeholders of prompt template 710 of FIG. 7. initiates a base design update. To generate the prompt for an update of a generic base design, Prompt Generation Module 335 retrieves some or all the metadata for the generic base design from the base design repository 140 for insertion into the prompt template. Prompt Generation Module 335 may select a design modification prompt template, such as prompt template 720 of FIG. 7, when U/I Module 310 receives a design revision request from the administrator (e.g., via user interface 600b of FIG. 6B). Prompt Generation Module 335 may insert the administrator's revision request into a placeholder of prompt template 720.

GAI Interface Module 345 interfaces with GAI model 150 to provide prompts to GAI model 150 and receive responses from GAI model 150. Once Prompt Generation Module 335 generates a prompt as discussed above, GAI Interface Module 345 submits the prompts to GAI model 150. GAI Interface Module 345 also receives, from GAI model 150, responses to the submitted prompts. For example, GAI Interface Module 345 may receive metadata (e.g., metadata 220) for a new generic base design generated by GAI model 150. Upon receiving the metadata, GAI Interface Module 345 may perform initial validation for the updated metadata, including checking for corrupted data, checking syntax, and checking validity (e.g., checking that components included in the new base design are valid components for the base design). Once GAI Interface Module 345 performs the initial validation, U/I Module 310 may provide the new base design to an engineer (e.g., on admin device 112) for review, for example via user interface 600b of FIG. 6B.

GAI Update Module 340 continually provides new data to GAI model 150 to update GAI model 150 over time. The new data provided to GAI Module 340 provides GAI model 150 with the training to accurately generate new designs for emerging markets. The data that GAI Update Module 340 provides to GAI model 150 may include, for example, new laws and regulations for various countries, design data for new factories in various industries and installation locations, product specifications, industry standard documents, technical papers, etc. GAI Update Module 340 thus continually fine-tunes GAI model 150 to learn current industry standards, such that GAI model 150 may accurately tailor the new base designs for a specific industry and installation location.

In some embodiments, GAI Update Module 340 also provides GAI model 150 with finalized designs for industrial automation projects submitted by users. Finalized designs submitted by users are received by U/I Module 310. The finalized designs include detailed information about the configuration of the industrial automation project, including the industry, the installation location, and all industrial design selections made by the user of industrial design application 120. GAI model 150 updates learned information based on the finalized designs from the users of industrial design application 120. For example, GAI model 150 may learn, from processing finalized designs submitted from many users, that a certain selection has become more popular in a specific industry or country (e.g., engineers in Canada now select higher space factors for MCCs due to new regulations). As such, by continually providing GAI model 150 with finalized designs submitted by users, GAI model 150 stays up to date with current preferences in various industries and locations. GAI Update Module 340 may also provide GAI model 150 with other new industrial information in addition to the finalized designs submitted by users. For example, GAI Update Module 340 may provide GAI model 150 with new industrial product literature, new industry standard data, and new safety regulations data.

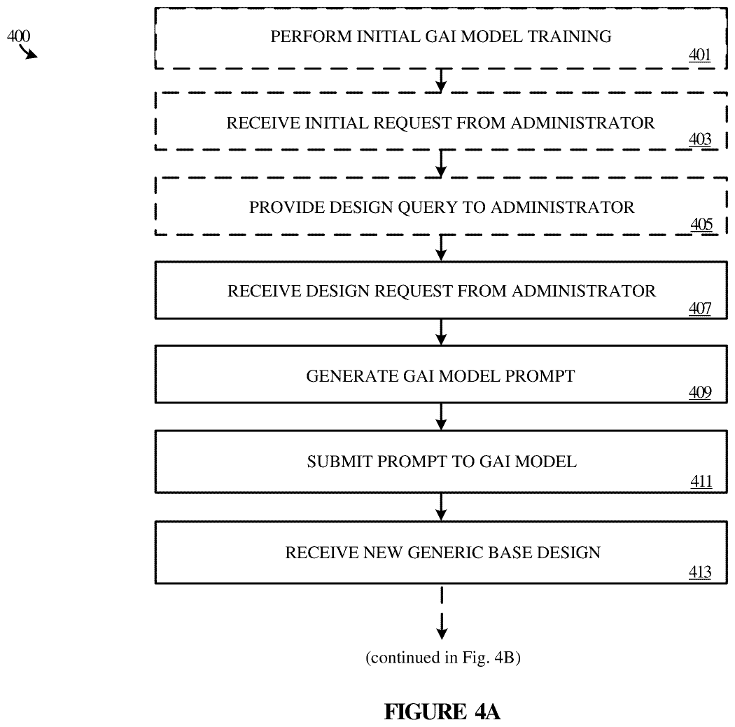

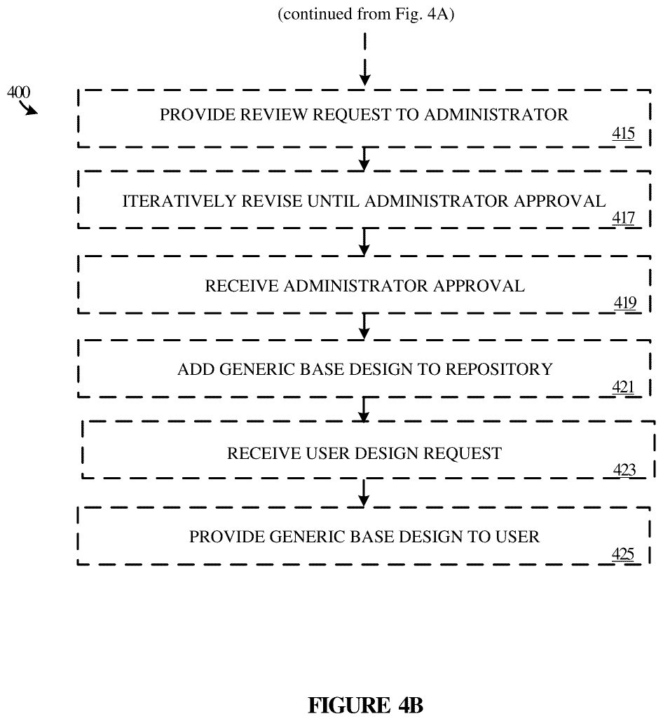

FIGS. 4A and 4B illustrate computer-implemented method 400 for industrial design generation performed according to some embodiments.

Step 401 of the method 400 is performing initial GAI model 150 training. Step 401 may be performed by GAI Update Module 340. In training GAI model 150, parameters of GAI model 150 are adjusted to encode learned information. Initial training of GAI model 150 is generally performed on a base model. A base model may be licensed and hosted by a third party, purchased, or acquired as an open-source model. The base model may have been pre-trained on a vast amount of data. In general, however, a base model is not specifically trained to perform industrial design functions. The initial training in step 401 fine-tunes GAI model 150 to perform industrial design tasks. The initial training in step 401 may be an unsupervised learning process using static data provided to GAI model 150. The static data may include industrial product literature associated with the various types of industrial units, industry standard data associated with the various industry types, and safety regulations data associated with the various installation locations, and other data relevant to the industrial systems. In step 401, GAI model 150 may also be provided with the metadata of the existing base designs in base design repository 140, where the metadata (such as metadata 220 of FIG. 2) includes associated industry types and installation locations for each base design.

Step 403 of method 400 is receiving, from an administrator, an initial request for industrial design assistance. Step 403 may be performed by U/I Module 310 of FIG. 3. An administrator on admin device 112, for example, make a selection indicating a request to generate a new generic base design with GAI model 150 assistance. The administrator may also make the initial request by, for example, by clicking a link to user interface 600a of FIG. 6A. The administrator may desire GAI model 150 assistance when the administrator needs to create a new generic base design for base design repository 140. This may occur, for example, when a customer is requesting a design for an industrial automation system in an emerging market (e.g., a new industry for a specific country). Current generic base designs in base design repository 140 may not meet the peculiar needs of the emerging market. The administrator may therefore wish to create a new generic base design that is appropriate for use in the emerging market.

Step 405 of method 400 is providing a design query to the administrator. Step 405 may be performed by U/I Module 310 of FIG. 3. An example design query is shown in user interface 600a of FIG. 6A. The design query may prompt administrator to input parameter values (e.g., by typing in text strings or selecting options from a drop-down menu. The parameters values, as shown in FIG. 6A, may include a unit type, an industry or plant type, an installation location, and additional requests. The design prompt may include a text input field (e.g., text input fields 630a, 630b, 630c, 630d) associated with each parameter value for the user to input text responses. It is noted that other embodiments may include other user input means (such as drop-down menus) for queries such as “Installation Location” that have a definite number of possible options. The design query of step 405 allows the administrator to quickly enter the most important details of the new generic base design for inclusion in a model prompt.

Step 407 of method 400 is receiving the design request from the administrator. Step 407 may be performed by U/I Module 310 of FIG. 3. The design request includes the parameter values input by the administrator, for example, in user interface 600a of FIG. 6A. The design request may thus include, for example, the information input by the user into text input fields 630a, 630b, 630c, and 630d of FIG. 6A in response to the queries in the design query.

Step 409 of the method 400 is generating a prompt for GAI model 150. Step 409 may be performed by Prompt Generation Module 335 of FIG. 3. Generating the prompt includes extracting the parameters from the administrator's design request and inserting them into placeholders of a prompt template such as prompt template 710 of FIG. 7. The model prompt further includes a request to generate a new generic base design for base design repository 140 based on the request details in the user inputs. As such, the prompt generated in step 409 is tailored to generate a new optimized to suit the unique needs of an emerging market.

In some embodiments, the generating the prompt of step 409 further includes inserting metadata (such as metadata 220 of FIG. 2) of an existing base design into the prompt template, where the prompt further includes a request to modify the metadata of the existing base design to meet constraints associated with the parameter values input by the administrator. The existing base design may be selected by Prompt Generation Module 335 based on the parameter values. For example, even though base design repository 140 may not have a design that meets the constraints associated with the parameter values, it may contain base designs for the same unit type in similar industry types or similar installation locations (i.e., industry types or installation locations with similar constraints). Once Prompt Generation Module 335 selects the base design, it retrieves the metadata from base design repository 140 and inserts the metadata into an appropriate placeholder in the prompt template. Utilizing existing metadata may improve the accuracy of the new designs generated by GAI model 150. However, it is noted that in other embodiments, the prompts generated for GAI model 150 may not include metadata for existing base designs.

Step 411 of method 400 is submitting the prompt to GAI model 150. Step 411 may be performed by GAI Interface Module 345.

Step 413 of method 400 is receiving a new generic base design from GAI model 150. The new generic base design is generated by GAI model 150 based on contextual information provided in the model prompt, including the user inputs of the design request. GAI model 150 also generates the generic base design based on learned industrial information, including preferences of users and industrial standards in similar areas and industries, industrial specifications, and applicable laws and regulations. It is noted that without AI assistance, it is difficult for engineers to consider all relevant information when creating industrial designs for emerging markets. Since GAI model 150 has been trained existing base designs and associated industry types and installation locations, GAI model 150 may make associations with similar industry types and installation locations as the industry type and installation location set forth in the prompt. This is beneficial, for example, in emerging markets in which there may not be any designs of the same unit type for the defined industry type and installation location. The use of GAI model 150 thus facilitates high quality industrial design, since it utilized a wide range of learned industrial information to generate base designs.

The new generic base design generated by GAI model 150 is a complete industrial design for a functional industrial unit, and may be represented, for example, by base design 200 shown in FIG. 2. The generic base design received in step 413 may include metadata defining the new base design, such as metadata 220 of FIG. 2. Thus, such a design may include the arrangement of components within the industrial unit, materials used, configuration options, option packs, default selections, and any other information discussed in FIG. 2 above.

Step 415 of method 400 is providing a review request to the administrator. Step 415 may be performed by U/I Module 310 of FIG. 3. The review request is shown, for example, in user interface 600b of FIG. 6B. The user may either approve the design or request further revisions, as discussed in further detail in FIG. 6B below. If the user approves the design, method 400 continues at step 419 below, skipping step 417. If the user desires to make changes to the design, the user may type in the revision request, for example in text input field 680 of FIG. 6B. The user may then submit the revision request for further modification, for example by clicking button 690 of FIG. 6B. The submission of a revision request initiates the iterative revision process of step 417 below.

Step 417 of method 400 is iteratively revising the design until the administrator approves of the generic base design. Specifically, when the user submits a revision request, a revision prompt for GAI model 150 is generated (for example, by Prompt Generation Module 335 of FIG. 3). The revision prompt may be generated based on a prompt template, for example prompt template 720 of FIG. 7. The generated prompt includes the revision request of the administrator as well as the generic base design to be revised. The revision prompt is submitted to the GAI model 150 (for example by GAI Interface Module 345 of FIG. 3), and GAI model 150 responds with a revised generic base design. The revised generic base design is generated by GAI model 150 based on contextual information in the revision prompt including the administrator's revision request, as well as the learned industrial information discussed in step 413 above. The revised generic base design may then be provided to the administrator in a review request (just as in step 415 above), for example in user interface 600b of FIG. 6B. Again, the administrator has the option to either approve the generic base design (as revised) or submit an additional revision request. If the administrator submits an additional revision request, the iterative process of step 417 continues, and the processes set forth in this paragraph are repeated. If the administrator approves the revised generic base design, the method continues at step 419, as discussed below.

Step 419 of method 400 is receiving administrator approval of the generic base design. Step 419 may be performed by U/I Module 310 of FIG. 3. The administrator may approve the generic base design, for example, by clicking button 670 of FIG. 6B.

Step 421 of method 400 is adding the generic base design to the base design repository 140. Step 421 may be performed by Repository Update Module 313 of FIG. 3. Once the administrator approves the generic base design, the generic base design is added to base design repository 140. It is noted that some embodiments may include additional vetting steps. For example, some embodiments may include review of multiple administrators before adding the generic base design to base design repository 140.

Step 423 of method 400 is receiving a design request from a user. Step 423 may be performed by U/I Module 310. A user, such as a user on user device 110 of FIG. 1, may log in to industrial design application 120 to make a request for a design of an industrial automation system. For example, the user may make a request for an MCC, where the request includes a motor-load list indicating high-level information about motor-controllers to be included in the MCC.

Step 425 of method 400 is providing the new generic base design to the user. Step 425 may be performed by U/I Module 310 of FIG. 3. In general, the industrial design application 120 selects generic base designs from base design repository 140 to meet the needs of the user's design request submitted in step 423. As such, after the new generic base design is added to base design repository 140, it may be provided to users who submit design requests in industrial design application 120. It is noted that related applications, incorporated by reference above, describe that GAI model 150 may be further utilized to customize the generic base designs to align with user-specific preferences associated with the user making the design request.

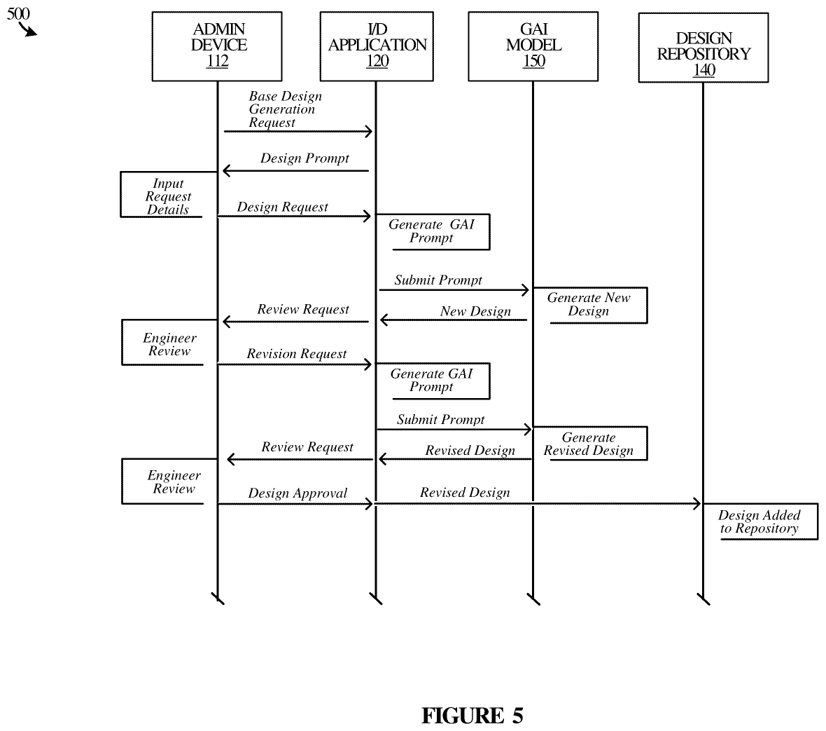

FIG. 5 illustrates an operational scenario 500. Operational scenario 500 includes user device 110, industrial design application 120, base design repository 140, and GAI model 150.

An administrator on admin device 112 submits a request to industrial design application 120 (for example, via U/I Module 310). The administrator may request GAI model assistance for the creation of a new generic base design. The administrator may make the request, for example, by clicking a link to visit user interface 600a of FIG. 6A. In response, industrial design application 120 provides (e.g., via U/I Module 310) a design query to the administrator on admin device 112. An example design query is portrayed in user interface 600a of FIG. 6A. The prompt query may have corresponding text fields for the administrator to input parameter values or drop-down lists (where there are a limited number of possible selections) for administrators to make selections. Upon receiving the prompt, the administrator inputs details about the request into the text input fields of the prompt, as shown, for example, in FIG. 6A. The administrator may then submit the design request, which is received by industrial design application 120 (for example, via U/I Module 310 of FIG. 3).

Once industrial design application 120 receives the administrator's submission of the design request, it generates a model prompt for GAI model 150 (e.g., with Prompt Generation Module 335). The model prompt is generated by a prompt template, for example prompt template 710 of FIG. 7. The model prompt is generated by replacing the placeholders of prompt template 710 with the corresponding administrator inputs from the design request. The prompt also includes a request to respond with a new generic base design, as well as a request to generate the design based on applicable laws and regulations and industry standards in similar industries and installation locations. Once the prompt has been generated by industrial design application 120, industrial design application 120 submits the prompt to GAI model 150 (for example, via GAI Interface Module 345).

Based on the contextual information of the prompt, GAI model 150 generates a new generic base design. GAI model 150 generates the new generic base design based on contextual information in the prompt, including the parameters set forth in the administrator's design request. GAI model 150 further generates the new generic base design based on learned industrial information. It is noted that the administrator's design request may often include a request for a design of an industrial unit for use in an emerging industry (e.g., a new industry in a particular country). In such cases, there may not be established industry standards that have been learned by GAI model 150 for the specific market. As such, GAI model 150 may generate a new generic base design based, in part, on industry standards in similar industries and locations. It is noted that without GAI model assistance, it is generally difficult for engineers to make design decisions for industrial designs used in emerging markets, as industry standards have not been well established. Furthermore, it is challenging for individuals to consider all relevant information from similar industries when making design decisions, even for experienced engineers. The GAI model assisted industrial designs of the present application accelerate the design process and provides quality industrial designs for emerging industries by considering a vast amount of learned industrial information.

Once GAI model 150 has generated a new generic base design, the new design is returned to the industrial design application (for example, via GAI Interface Module 345). Industrial design application 120 then provides a review request including the new generic base design to the administrator on admin device 112 (for example, via U/I Module 310). An example review request is shown, for example, in user interface 600b of FIG. 6B. User interface 600b includes several options for the administrator to choose between, as discussed in further detail in FIG. 6B below. In operational scenario 500 in FIG. 5, the administrator reviews the new generic base design and desires to make some changes to the system. As such, the administrator may submit a review request by, for example, typing the request into text input field 680 of FIG. 6, and clicking button 690 to submit the request.

Once industrial design application 120 receives a revision request (for example, via U/I Module 310), it generates a revision prompt for GAI model 150. The revision prompt may be generated by Prompt Generation Module 335 based on a prompt template, such as prompt template 720 of FIG. 7. The revision prompt may include the administrator's revision request, as well as a request to respond with a revised generic base design based on the administrator's revision request. Once the revision prompt is generated, the revision prompt is submitted to GAI model 150 (for example, via GAI Interface Module 345 of FIG. 3). GAI model 150 generates a revised generic base design. GAI model 150 may take into account contextual information of the prompt, including the new generic base design, and the administrator's revision request. GAI model 150 also utilizes the learned industrial information to provide a revised generic base design in accordance with the revision request.

Once industrial design application 120 receives a revised generic base design from GAI model 150 (for example, via GAI Interface Module 345), the application provides a new review request to the administrator, including the new generic base design. The new review request may be presented in the same user interface as the original review request (e.g., user interface 600b of FIG. 6B). The administrator may then have the opportunity to submit another revision request. Thus, the administrator may iterate the design with the assistance of GAI model 150 until the desired design is achieved. In operational scenario 500 of FIG. 5, the administrator submits an approval of the revised generic base design, for example by clicking button 670 of FIG. 6B. Once industrial design application 120 receives the approval of the design from admin device 112, the revised generic base design may be added to base design repository 140 (for example, by Repository Update Module 313 of FIG. 3). It is noted that there may be additional review steps before the generic base design is added to the repository. For example, the generic base design may need to be reviewed by additional administrators/engineers for compliance with industry standards before the base design is added to base design repository 140.

FIGS. 6A and 6B show user interfaces 600a and 600b of industrial design application 120 according to some embodiments. User interfaces 600a, 600b may be displayed to an administrator on a display of admin devices 112 of FIG. 1. User interfaces 600a, 600b may be viewed in an internet browser in a separate application on admin device 112. FIGS. 6A and 6B show an example in which an administrator is requesting a base design for a VFD. However, it is noted that other embodiments of the present technology may include requests for designs of other industrial units, components, and systems.

FIG. 6A shows user interface 600a according to some embodiments. User interface 600a may be provided to administrators on admin devices 112. User interface 600a may be provided to the administrator when the administrator makes a request for GAI model assistance to generate a generic base design. User interface 600a may be provided to the administrator, for example, in step 405 of method 400 discussed above. User interface 600a includes multiple queries to the administrator. FIG. 6A shows first query 620a requesting user input of the unit type of the requested design. First text input field 630a is associated with first query 620a. Here, the user may indicate, for example, the type of motor controller and the power rating of the requested design. The user may also request a design for an entire MCC. For example, an administrator may input, into the first text input field “A low-motor control center with five VFD motor Controllers and 3 DOL motor controllers.” The use of text input fields in user interface 600a gives the administrator a wide latitude on how the administrator crafts the design request for GAI model 150.

FIG. 6A further shows second query 620b requesting user input of the industry or plant type of the requested design. Second text input field 630b is associated with first query 620a. Here the administrator may input an industry, such as “Food and Beverage” or a plant type, such as “Water Bottling Plant.” Furthermore, the administrator may type in multiple industries or plant types if the administrator desires the industrial unit to be applicable across multiple industries. Third query 620c requests user input of the installation location. Third text input field 630c is associated with third query 620a, for the administrator to input the country or countries applicable as installation locations for the generic base design.

Fourth query 620d prompts the administrator to input any additional requests, which the administrator may type into fourth text input field 630d. The administrator may use this field to make a wide variety of requests. For example, the administrator could ask GAI model 150 to optimize the design for cost, or to customize the unit based on the preferences of a specific company (if the design is to be included, for example in Company Design Library 375).

Once the administrator has input all the responses, the administrator may submit the design request to industrial design application 120 by clicking button 640 for submission. It is noted that the queries shown in FIG. 6A are representative. Other embodiments may include additional, fewer, or other combinations of various queries to include in the prompt for the administrator.

FIG. 6B shows user interface 600b according to some embodiments. User interface 600b is a review request for the administrator to review the new generic base design generated by GAI model 150. User interface 600B may be provided to the administrator, for example, in step 415 of method 400 discussed above. User interface 600b includes design display field 655, which gives an overview of the generated design. The administrator may see further design details by clicking button 660 to view a CAD file of the generated generic base design and may click button 665 to view detailed specifications for the generated generic base design. If the administrator approves the design, the administrator may click button 670 approving the design.

User interface 600b further includes revision query 675 prompting the administrator to input any desired revisions to the generic base design generated by GAI model 150. In text input field 680, the administrator may input any desired changes to the generic base design for GAI model to make. In the example of FIG. 6B, the administrator has typed in a request to increase the overall safety of the design and to change the operator station to include a HIM. In response to this request, GAI model 150 may revise various features of the generic base design to increase its safety, such as changing the safety category, switching to a more sensitive circuit breaker, and switching to safer circuit protection. The revised generic base design would also include a HIM in the operator station. In the example in FIG. 6B, user interface 600b further includes button 695 which the administrator may select to manually edit the generic base design (as an alternative to sending a revision request to GAI model 150).

FIG. 7 illustrates prompt templates 710, 720 according to some embodiments. Prompt templates 710, 720 are files stored in the industrial design application 120 (for example, in Prompt Generation Module 335). Prompt templates 710, 720 may include a combination of text and placeholders, where the placeholders are replaced with the relevant data during prompt generation as discussed below. It is noted that in some embodiments prompt templates 710, 720 may include additional or fewer placeholders. Prompt templates 710, 720 may be utilized, for example, by Prompt Generation Module 335 of FIG. 3 to generate prompts for GAI model 150.

Prompt template 710 may be used to generate an initial request for a new generic base design. Prompt template 710 is utilized by Prompt Generation Module 335 of FIG. 3. Prompt template 710 includes multiple placeholders that are filled in with appropriate data to generate the prompt. The placeholders in prompt template 710 include <Response 1>, <Response 2>, <Response 3>, and <Response 4>. To generate a prompt for GAI Model 150, the industrial design application 120 (e.g., Prompt Generation Module 335) replaces the placeholder <Response 1> with the user's input into text input field 630a of FIG. 6A. The placeholder <Response 2> is replaced with the user's input into text input field 630b of FIG. 6A. The placeholder <Response 3> is replaced with the user's input into text input field 630c of FIG. 6A. The placeholder <Response 4> is replaced with the user's input into text input field 630d of FIG. 6A. Prompt template 710 includes a request for GAI model 150 to respond with a new generic base design in base design format. While prompt template 710 shows “[base design format]” for representative purposes, it should be understood that other embodiments use other language for the format request in prompt template 710. Prompt template 710 further includes a request to generate the new design based on applicable laws and regulations, and industry standards in similar industries and installation locations. As discussed above, GAI model 150 is trained on industrial designs for various industry types and installation locations. As such, GAI model 150 may generate new designs for emerging markets based on associations with existing markets in similar industry types and installation locations.

Prompt template 720 may be used when the administrator makes a request to revise a new generic base design. Prompt template 720 is utilized, for example, in the revisions of step 417 of method 400. An administrator may make input a revision request, for example in text input field 680 of FIG. 6B. The administrator may submit the request, for example by clicking button 690 of FIG. 6B. To generate a prompt based on prompt template 720, the administrator revision request from text input field 680 replaces the placeholder <User Revision Request> in prompt template 720. The metadata of the new base design (e.g., metadata 220 of FIG. 2) to be revised is also inserted into the placeholder <new generic base design>. Prompt template 720 also includes a request to revise the new generic base design based on the user's revision request.

Once the prompt is generated based on the prompt template, and the prompt is provided to GAI model 150, GAI model 150 uses the information in the prompt as contextual information to generate or revise generic base designs. It is noted that prompt templates 710, 720 are representative. Other embodiments may include different request language, and may include additional placeholders, or fewer placeholders.

FIG. 8 illustrates computing device 801 that is representative of any system or collection of systems in which the various processes, programs, services, and scenarios disclosed herein may be implemented. Examples of computing device 801 include, but are not limited to, desktop and laptop computers, tablet computers, mobile computers, and wearable devices. Examples may also include server computers, web servers, cloud computing platforms, and data center equipment, as well as any other type of physical or virtual server machine, container, and any variation or combination thereof.

Computing device 801 may be implemented as a single apparatus, system, or device or may be implemented in a distributed manner as multiple apparatuses, systems, or devices. Computing device 801 includes, but is not limited to, processing system 802, storage system 803, software 805, communication interface system 807, and user interface system 809. Processing system 802 is operatively coupled with storage system 803, communication interface system 807, and user interface system 809.

Processing system 802 loads and executes software 805 from storage system 803. Software 805 includes and implements the industrial design application 120 which is representative of the application service processes discussed with respect to the preceding figures, such as the method 400 of FIGS. 4A and 4B. When executed by the processing system 802, software 805 directs processing system 802 to operate as described herein for at least the various processes, operational scenarios, and sequences discussed in the foregoing implementations. Computing device 801 may optionally include additional devices, features, or functionality not discussed for purposes of brevity.

Referring still to FIG. 8, processing system 802 may include a microprocessor and other circuitry that retrieves and executes software 805 from storage system 803. Processing system 802 may be implemented within a single processing device but may also be distributed across multiple processing devices or sub-systems that cooperate in executing program instructions. Examples of processing system 802 include general purpose central processing units, graphical processing units, application specific processors, and logic devices, as well as any other type of processing device, combinations, or variations thereof.

Storage system 803 may comprise any computer-readable storage media device readable by processing system 802 and capable of storing software 805. Storage system 803 may include volatile and nonvolatile, removable and non-removable media implemented in any method or technology for storage of information, such as computer readable instructions, data structures, program modules, or other data. Examples of storage media include random access memory, read only memory, magnetic disks, optical disks, flash memory, virtual memory and non-virtual memory, magnetic cassettes, magnetic tape, magnetic disk storage or other magnetic storage devices, or any other suitable storage media. In no case is the computer readable storage media a propagated or transitory signal.

In addition to computer-readable storage media, in some implementations the storage system 803 may also include computer readable communication media over which at least some of the software 805 may be communicated internally or externally. The storage system 803 may be implemented as a single storage device but may also be implemented across multiple storage devices or sub-systems co-located or distributed relative to each other. The storage system 803 may comprise additional elements, such as a controller, capable of communicating with the processing system 802 or possibly other systems.

Software 805 (including industrial design application 120) may be implemented in program instructions and among other functions may, when executed by processing system 802, direct processing system 802 to operate as described with respect to the various operational scenarios, sequences, and processes illustrated herein. For example, software 805 may include program instructions for implementing an application service process as described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 805 may include additional processes, programs, or components, such as operating system software, virtualization software, or other application software. Software 805 may also comprise firmware or some other form of machine-readable processing instructions executable by processing system 802.

In general, software 805 may, when loaded into processing system 802 and executed, transform a suitable apparatus, system, or device (of which computing device 801 is representative) overall from a general-purpose computing system into a special-purpose computing system customized to support an application service in an optimized manner. Indeed, encoding software 805 on storage system 803 may transform the physical structure of storage system 803. The specific transformation of the physical structure may depend on various factors in different implementations of this description. Examples of such factors may include, but are not limited to, the technology used to implement the storage media of storage system 803 and whether the computer-storage media are characterized as primary or secondary storage, as well as other factors.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number, respectively. The word “or,” in reference to a list of two or more items, covers all of the following interpretations of the word: any of the items in the list, all of the items in the list, and any combination of the items in the list.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or blocks are presented in a given order, alternative implementations may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed or implemented in parallel or may be performed at different times. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112(f) will begin with the words “means for”, but use of the term “for” in any other context is not intended to invoke treatment under 35 U.S.C. § 112(f). Accordingly, the applicant reserves the right to pursue additional claims after filing this application to pursue such additional claim forms, in either this application or in a continuing application.

The phrases “in some embodiments,” “according to some embodiments,” “in the embodiments shown,” “in other embodiments,” and the like generally mean the particular feature, structure, or characteristic following the phrase is included in at least one implementation of the present technology and may be included in more than one implementation. In addition, such phrases do not necessarily refer to the same embodiments or different embodiments. The phrases “in some embodiments,” “according to some embodiments,” “in the embodiments shown,” “in other embodiments,” and the like generally mean the particular feature, structure, or characteristic following the phrase is included in at least one implementation of the present technology and may be included in more than one implementation. In addition, such phrases do not necessarily refer to the same embodiments or different embodiments.

What is claimed is:

1. A computer-implemented method for updating an industrial design database, the method comprising:
receiving from an administrator of an industrial design application, via a user interface, a design request to generate a base design for an industrial unit, the design request comprising a plurality of parameter values, wherein corresponding parameters to the parameter values include a type of the industrial unit, an installation location, and an industry type;
generating a model prompt to elicit a response from a Generative Artificial Intelligence (GAI) model trained on a plurality of existing base designs associated with a plurality of types of industrial units, a plurality of industry types and a plurality of installation locations, the model prompt comprising the plurality of parameter values and a request to generate a new base design for the industrial unit based on plurality of parameter values;
submitting the prompt to the GAI model;
receiving from the GAI model, in response to the prompt, the new base design generated by the GAI model based on the plurality of parameter values; and
providing to the administrator, via the user interface, a review request comprising the new base design.

2. The computer-implemented method of claim 1, wherein the review request further comprises:
a first selectable option to approve the new base design,
a revision query prompting the administrator to input a revision request for the new base design, and
a second selectable option for the administrator to submit the revision request; and
wherein the method further comprises:
generating a revision prompt for the GAI model, the revision prompt comprising the revision input and metadata of the new base design;
submitting the revision prompt to the GAI model;
receiving, from the GAI model in response to the revision prompt, a revised generic base design; and
providing, to the administrator via the user interface, an updated review request comprising the revised generic base design, the first selectable option, and the second selectable option.

3. The computer-implemented method of claim 1, wherein the review request further comprises:
the new base design,
a first selectable option to approve the new base design,
a revision query prompting the administrator to input a revision request for the new base design, and
a second selectable option for the administrator to submit the revision request; and
wherein the method further comprises:
receiving a selection of the first selectable option indicating an approval of the new base design; and
adding, in response to the selection, the new base design to a base design repository, wherein the base design repository stores a plurality of generic base designs for industrial units.

4. The computer-implemented method of claim 3, further comprising:
receiving a request from a user of the industrial design application for a design for an industrial automation project; and
providing to the user, in response to the request for a design, an initial layout of an industrial automation project, the initial layout including the new base design.

5. The computer-implemented method of claim 1, the method further comprising:
providing the GAI model with static data during initial training, the static data comprising one or more of: industrial product literature associated with the plurality of types of industrial units, industry standard data associated with the plurality of industry types, and safety regulations data associated with the plurality of installation locations.

6. The computer-implemented method of claim 1, further comprising:
selecting an existing base design from the plurality of existing base designs based on the plurality of parameter values, wherein the model prompt further comprises:
metadata associated with the existing base design, and
wherein the request to generate the new base design further comprises a request to modify the metadata of the existing base design to achieve a design that meets constraints associated with the plurality of parameter values.

7. The computer-implemented method of claim 1, further comprising:
receiving, from an administrator via a user interface of an industrial design application, an initial request for industrial design assistance; and
providing to the administrator via the user interface, in response to the initial request, a design query prompting the administrator to input the parameter values, wherein the receiving the design request from the administrator is in response to providing the design query to the administrator.

8. The computer-implemented method of claim 1, wherein the design request to generate a base design for an industrial unit comprises a design request to generate a base design for a motor controller unit.

9. A system for updating an industrial design database, the system comprising:
one or more processors; and
one or more memories operably coupled to the one or more processors and having stored thereon software instructions that, upon execution by the one or more processors, cause the one or more processors to:
receive from an administrator of an industrial design application, via a user interface, a design request to generate a base design for an industrial unit, the design request comprising a plurality of parameter values, wherein corresponding parameters to the parameter values include a type of the industrial unit, an installation location, and an industry type;
generate a model prompt to elicit a response from a Generative Artificial Intelligence (GAI) model trained on a plurality of existing base designs associated with a plurality of types of industrial units, a plurality of industry types and a plurality of installation locations, the model prompt comprising the plurality of parameter values and a request to generate a new base design for the industrial unit based on plurality of parameter values;
submit the prompt to the GAI model;
receive from the GAI model, in response to the prompt, the new base design generated by the GAI model based on the plurality of parameter values; and
provide to the administrator, via the user interface, a review request comprising the new base design.

10. The system of claim 9, wherein the review request further comprises:
a first selectable option to approve the new base design,
a revision query prompting the administrator to input a revision request for the new base design, and
a second selectable option for the administrator to submit the revision request; and
wherein the software instructions comprise further instructions that, upon execution by the one or more processors, cause the one or more processors to:
generate a revision prompt for the GAI model, the revision prompt comprising the revision input and metadata of the new base design;
submit the revision prompt to the GAI model;
receive, from the GAI model in response to the revision prompt, a revised generic base design; and
provide, to the administrator via the user interface, an updated review request comprising the revised generic base design, the first selectable option, and the second selectable option.

11. The system of claim 9, wherein the review request further comprises:
a first selectable option to approve the new base design,
a revision query prompting the administrator to input a revision request for the new base design, and
a second selectable option for the administrator to submit the revision request; and
wherein the software instructions comprise further instructions that, upon execution by the one or more processors, cause the one or more processors to:
receive a selection of the first selectable option indicating an approval of the new base design; and
add, in response to the selection, the new base design to a base design repository, wherein the base design repository stores a plurality of generic base designs for industrial units.

12. The system of claim 11, wherein the software instructions comprise further instructions that, upon execution by the one or more processors, cause the one or more processors to:
receive a request from a user of the industrial design application for a design for an industrial automation project; and
provide to the user, in response to the request for a design, an initial layout of an industrial automation project, the initial layout including the new base design.

13. The system of claim 9, wherein the software instructions comprise further instructions that, upon execution by the one or more processors, cause the one or more processors to:
provide the GAI model with static data during initial training, the static data comprising one or more of: industrial product literature associated with the plurality of types of industrial units, industry standard data associated with the plurality of industry types, and safety regulations data associated with the plurality of installation locations.

14. The system of claim 9, wherein the software instructions comprise further instructions that, upon execution by the one or more processors, cause the one or more processors to:
select an existing base design from the plurality of existing base designs based on the plurality of parameter values, wherein the model prompt further comprises:
metadata associated with the existing base design, and
wherein the request to generate the new base design further comprises a request to modify the metadata of the existing base design to achieve a design that meets constraints associated with the plurality of parameter values.

15. The system of claim 9, wherein the software instructions comprise further instructions that, upon execution by the one or more processors, cause the one or more processors to:
receive, from an administrator via a user interface of an industrial design application, an initial request for industrial design assistance; and
provide to the administrator via the user interface, in response to the initial request, a design query prompting the administrator to input the parameter values, wherein the receiving the design request from the administrator is in response to providing the design query to the administrator.

16. The system of claim 9, wherein the design request to generate a base design for an industrial unit comprises a design request to generate a base design for a motor controller unit.

17. A computer-readable storage media device having program instructions stored thereon for updating an industrial design database, wherein the program instructions, upon execution by one or more processors, cause the one or more processors to:
receive from an administrator of an industrial design application, via a user interface, a design request to generate a base design for an industrial unit, the design request comprising a plurality of parameter values, wherein corresponding parameters to the parameter values include a type of the industrial unit, an installation location, and an industry type;
generate a model prompt to elicit a response from a Generative Artificial Intelligence (GAI) model trained on a plurality of existing base designs associated with a plurality of types of industrial units, a plurality of industry types and a plurality of installation locations, the model prompt comprising the plurality of parameter values and a request to generate a new base design for the industrial unit based on plurality of parameter values;
submit the prompt to the GAI model;
receive from the GAI model, in response to the prompt, the new base design generated by the GAI model based on the plurality of parameter values; and
provide to the administrator, via the user interface, a review request comprising the new base design.

18. The computer-readable storage media device of claim 17, wherein the review request further comprises:
a first selectable option to approve the new base design,
a revision query prompting the administrator to input a revision request for the new base design, and
a second selectable option for the administrator to submit the revision request; and
wherein the program instructions comprise further instructions, that, upon execution by the one or more processors, cause the one or more processors to:
generate a revision prompt for the GAI model, the revision prompt comprising the revision input and metadata of the new base design;
submit the revision prompt to the GAI model;
receive, from the GAI model in response to the revision prompt, a revised generic base design; and
provide, to the administrator via the user interface, an updated review request comprising the revised generic base design, the first selectable option, and the second selectable option.

19. The computer-readable storage media device of claim 17, wherein the review request further comprises:
a first selectable option to approve the new base design,
a revision query prompting the administrator to input a revision request for the new base design, and
a second selectable option for the administrator to submit the revision request, and wherein the program instructions comprise further program instructions that, upon execution by the one or more processors, cause the one or more processors to:
receive a selection of the first selectable option indicating an approval of the new base design; and
add, in response to the selection, the new base design to a base design repository, wherein the base design repository stores a plurality of generic base designs for industrial units.

20. The computer-readable storage media device of claim 19, wherein the program instructions comprise further program instructions that, upon execution by the one or more processors, cause the one or more processors to:
receive a request from a user of the industrial design application for a design for an industrial automation project; and
provide to the user, in response to the request for a design, an initial layout of an industrial automation project, the initial layout including the new base design.
